(19) United States
(12) Patent Application Publication
(10) Pub. No.: US 2018/0290882 A1
(43) Pub. Date: Oct. 11, 2018

(54) SEMICONDUCTOR PACKAGES AND METHODS FOR FABRICATING SEMICONDUCTOR PACKAGES

(71) Applicant: Agency for Science, Technology and Research, Singapore (SG)

(72) Inventors: Daniel Minwoo Rhee, Singapore (SG); Peter Hyun Kee Chang, Singapore (SG)

(21) Appl. No.: 15/574,349

(22) PCT Filed: Jun. 10, 2016
(86) PCT No.: PCT/SG2016/050268

§ 371 Date: Nov. 15, 2017

(30) Foreign Application Priority Data
Jun. 17, 2015 (SG) 10201504804R

(51) Int. Cl. B81B 7/00; B81C 1/00

(52) U.S. Cl. CPC B81B 7/007; B81C 1/00269; B81C 1/00301; B81B 2207/097; B81C 2201/0132; B81C 2203/0118; B81C 2203/019; B81B 7/0058

(57) ABSTRACT

According to various embodiments, there is provided a method for fabricating a semiconductor package, the method including forming a cap structure and a pillar from a first wafer; bonding the first wafer to a second wafer; and filling a gap between the pillar and the cap structure with a mold compound.

### CROSS-REFERENCE TO RELATED APPLICATIONS

This application claims the benefit of Singapore Patent Application number 10201504804R filed 17 Jun. 2015, the entire contents of which are incorporated herein by reference for all purposes.

### TECHNICAL FIELD

The present invention relates to semiconductor packages and methods for fabricating semiconductor packages.

### BACKGROUND

Microelectromechanical Systems (MEMS) is rapidly becoming the technology for making a multitude of innovative products and solutions, in various types of mobile consumer applications. Many manufacturers are seeking lower cost and smaller-sized solutions that can be integrated into their new generation of products. MEMS devices may include MEMS structures that may need to be hermetically sealed or vacuum-sealed, in order to function properly. To achieve the hermetic sealing, semiconductor packages may include silicon based cap wafers bonded to the MEMS device wafer. The resulting MEMS capped wafer may be individualized using wafer sawing process and may be further processed by conventional packaging methods, such as die-attach or wire bonding. A MEMS capped wafer may face limitations in wafer level packaging because of its step structure. The MEMS capped wafer may be attached or bonded to a lead-frame or a printed circuit board (PCB) substrate. A semiconductor package may include a wire bonded stack module with a ball grid array (BGA). The MEMS capped wafer may be integrated with a read-out integrated circuit (IC) by wire bonding on a BGA substrate or lead frame based packaging. Direct ball bumping may be performed on the capped wafer for the wafer level bonding but this method presents the problem of leaving little space for both MEMS interconnection and the integration of the read out IC.

To reduce the number of process steps and to increase the manufacturability of the MEMS wafer packages, wafer level packaging processes such as through silicon via (TSV) and through glass via (TGV) have been introduced. Fabricating TSV based silicon wafers or TGV based glass wafers provides the benefit of being able to obtain hermetically sealed layer and signal bonding simultaneously. Through silicon interposer (TSI) or through glass interposer (TGI) may also be employed. However, the TSV, TGV, TSI and TGI based wafer processes are considered to be very expensive and complicated processes. In addition, the resulting board level reliability (BLR) may be low due to mismatches of coefficients of thermal expansion (CTE) between glass epoxy based PCB and silicon based MEMS packages.

As such, there is a need for a method for fabricating semiconductor packages through a simpler and more cost-effective process.

### SUMMARY

According to various embodiments, there may be provided a method for fabricating a semiconductor package, the method including forming a cap structure and a pillar from a first wafer; bonding the first wafer to a second wafer; and filling a gap between the pillar and the cap structure with a mold compound.

According to various embodiments, there may be provided a semiconductor package including a cap structure and a pillar formed from a first wafer; a second wafer bonded to the cap structure and the pillar; and a mold compound between the pillar and the cap structure.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments are described with reference to the following drawings, in which:

FIG. 1A shows a flow diagram showing a method for fabricating a semiconductor package, according to various embodiments

FIG. 1B shows a flow diagram showing a method for fabricating a semiconductor package, according to various embodiments.

FIG. 2A shows a semiconductor package according to various embodiments.

FIG. 2B shows a semiconductor package according to various embodiments.

FIG. 3 shows a semiconductor package according to various embodiments.

FIG. 4 shows a semiconductor package according to various embodiments.

FIGS. 5-10 show various processes in a method for fabricating a semiconductor package according to various embodiments.

FIGS. 11-18 show a method for fabricating a semiconductor package according to various embodiments.

FIG. 19 shows a schematic diagram of a conventional package on package structure.

FIG. 20 shows semiconductor package according to various embodiments.

FIG. 21 shows a microscopic photograph of the metal deposited silicon pillars.

### DESCRIPTION

Embodiments described below in context of the semiconductor packages are analogously valid for the respective methods, and vice versa. Furthermore, it will be understood that the embodiments described below may be combined, for example, a part of one embodiment may be combined with a part of another embodiment.

In the specification the term “comprising” shall be understood to have a broad meaning similar to the term “including” and will be understood to imply the inclusion of a stated integer or step or group of integers or steps but not the exclusion of any other integer or step or group of integers or steps. This definition also applies to variations on the term “comprising” such as “comprise” and “comprises”.

In order that the invention may be readily understood and put into practical effect, particular embodiments will now be described by way of examples and not limitations, and with reference to the figures.

Various embodiments are provided for semiconductor packages, and various embodiments are provided for methods. It will be understood that basic properties of the semiconductor packages also hold for the methods and vice versa. Therefore, for sake of brevity, duplicate description of such properties may be omitted.

It will be understood that any property described herein for a specific semiconductor package may also hold for any semiconductor package described herein. It will be understood that any property described herein for a specific method may also hold for any method described herein. Furthermore, it will be understood that for any semiconductor package or method described herein, not necessarily all the components or steps described must be enclosed in the semiconductor package or method, but only some (but not all) components or steps may be enclosed.

The term “coupled” (or “connected”) herein may be understood as electrically coupled or as mechanically coupled, for example attached or fixed, or just in contact without any fixation, and it will be understood that both direct coupling or indirect coupling (in other words: coupling without direct contact) may be provided.

It should be appreciated and understood that the term “substantially” may include “exactly” and “similar” which is to an extent that it may be perceived as being “exact”. For illustration purposes only and not as a limiting example, the term “substantially” may be quantified as a variance of +/−5% from the exact or actual.

Microelectromechanical Systems (MEMS) is rapidly becoming the technology for making a multitude of innovative products and solutions, in various types of mobile consumer applications. Many manufacturers are seeking lower cost and smaller-sized solutions that can be integrated into their new generation of products. MEMS devices may include MEMS structures that may need to be hermetically sealed or vacuum-sealed, in order to function properly. To achieve the hermetic sealing, semiconductor packages may include silicon based cap wafers bonded to the MEMS device wafer. The resulting MEMS capped wafer may be individualized using wafer sawing process and may be further processed by conventional packaging methods, such as die-attach or wire bonding. A MEMS capped wafer may face limitations in wafer level packaging because of its step structure. The MEMS capped wafer may be attached or bonded to a lead-frame or a printed circuit board (PCB) substrate. A semiconductor package may include a wire bonded stack module with a ball grid array (BGA). The MEMS capped wafer may be integrated with a read-out integrated circuit (IC) by wire bonding on a BGA substrate or lead frame based packaging. Direct ball bumping may be performed on the capped wafer for the wafer level bonding but this method presents the problem of leaving little space for both MEMS interconnection and the integration of the read out IC. To reduce the number of process steps and to increase the manufacturability of the MEMS wafer packages, wafer level packaging processes such as through silicon via (TSV) and through glass via (TGV) have been introduced. Fabricating TSV based silicon wafers or TGV based glass wafers provides the benefit of being able to obtain hermetically sealed layer and signal bonding simultaneously. Through silicon interposer (TSI) or through glass interposer (TGI) may also be employed. However, TSV, TGV, TSI and TGI based wafer processes are considered to be very expensive and complicated processes. In addition, the resulting board level reliability (BLR) may be low due to mismatches of coefficients of thermal expansion (CTE) between glass epoxy based PCB and silicon based MEMS packages. As such, there is a need for a method for fabricating semiconductor packages through a simpler and more cost-effective process.

According to various embodiments, a semiconductor package may include a capped wafer. The semiconductor package may include pillar structures formed out of a cap wafer that is used to hermetically seal the MEMS structure or MEMS device. The pillar structures may include at least one of high conductive silicon or metal-coated silicon. Instead of TSV or and TGV based wafer preparation processes, the semiconductor package may utilize the pillar structures fabricated from the MEMS cap wafer itself, to serve as an electrical interconnection array. The cap wafer may be etched to form ridges and valleys in the cap wafer. The cap wafer may be flipped and then bonded to a device wafer, such that the ridges are in contact with the device wafer. The valley walls may be at least substantially vertical. The ridges may also be referred herein as pillar structures, pillars or further pillars. The cap wafer may be further etched or grounded, so as to create openings for pouring a filler material into the now inverted valleys. The valleys may also be referred herein as gaps or further gaps. The filler material may be a mold compound. After filling the valleys, a top side of the cap wafer may be ground off to expose the pillar structures. A redistribution layer (RDL) may be provided to generate bonding pads, following which, solder bumps may be deposited. The bonding pads may provide an electrically conductive surface for integrating a functional device to the semiconductor package. The solder bumps may be used to provide board level interconnection to the semiconductor package.

In the context of various embodiments, “pillar” may be interchangeably referred to as “pillar structures”.

In the context of various embodiments, “cavity area” may be interchangeably referred to as “cavity”.

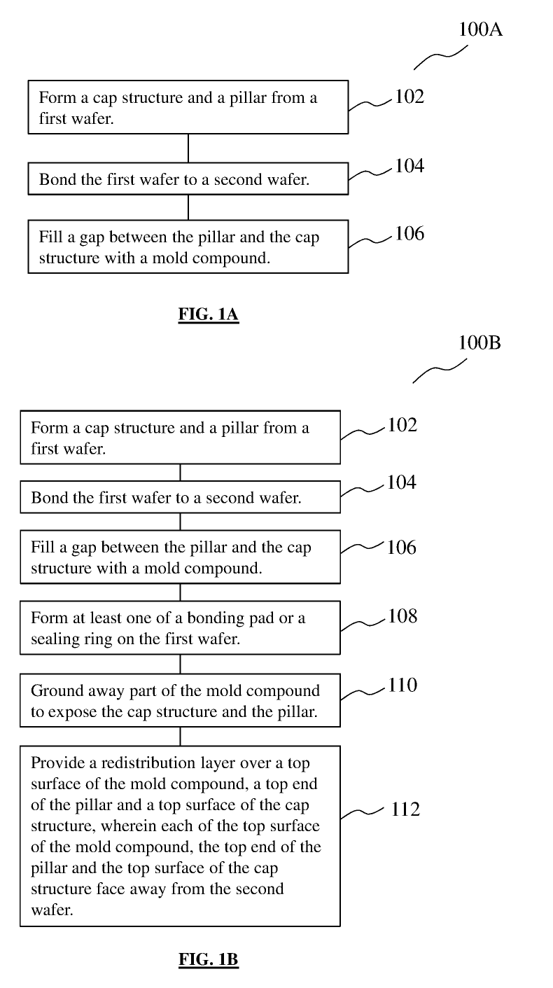

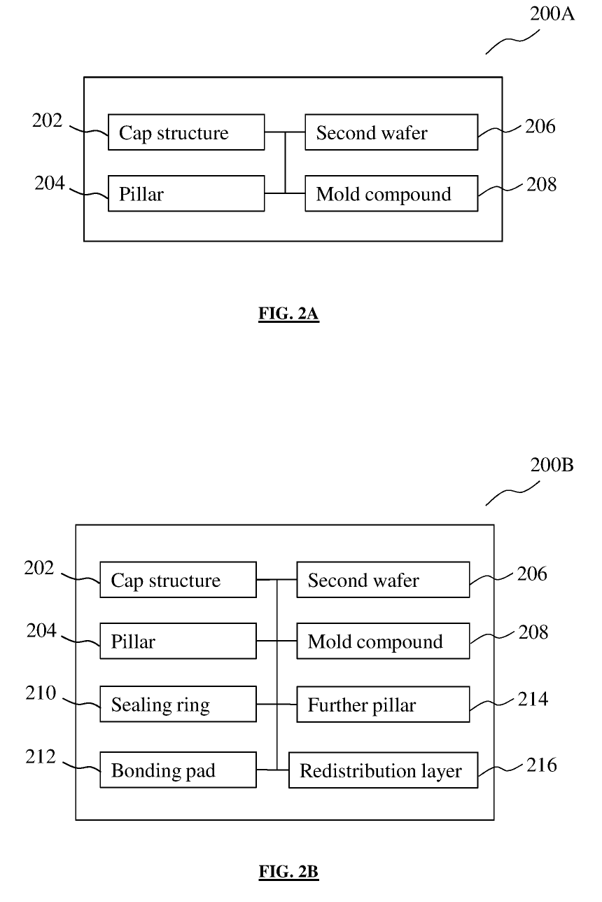

FIG. 1A shows a flow diagram 100A showing a method for fabricating a semiconductor package, according to various embodiments. In 102, a cap structure and a pillar may be formed from a first wafer. In 104, the first wafer may be bonded to a second wafer. In 106, a gap between the pillar and the cap structure may be filled with a mold compound.

In other words, according to various embodiments, a method for fabricating a semiconductor package may include forming a cap structure and a pillar. The pillar may be separated from the cap structure by a gap. The cap structure and the pillar may be formed from a first wafer. The first wafer may also be referred herein as a cap wafer. The first wafer may include conductive silicon. The conductive silicon may be for example, doped silicon. Forming the cap structure may include forming a cavity in the first wafer. Forming the pillar may include forming at least one groove in the first wafer. The cavity and the groove may be formed by an etching process, for example, including deep reactive ion-etching (DRIE). The etching process may include a first etching step and optionally, a second etching step. The first etching step may include forming the groove and the second etching step may include forming the cavity. The cavity may have a different depth from the groove. The first wafer may be bonded to a second wafer, following the formation of the cap structure and the pillar. The cap structure may at least substantially surround the cavity. The bonding of the first wafer to the second wafer may form a sealed cavity between the cap structure and the second wafer. The sealed cavity may hermetically seal a MEMS device. The second wafer may also be referred herein as a device wafer. The second wafer may include a MEMS device. An inner surface of the first wafer may be bonded to the second wafer after the groove and the cavity are formed, wherein the inner surface may be a surface of the first wafer whereat the groove and the cavity are formed. The process of forming the cap structure and the pillar may include removing part of the first wafer at an end of the groove to form the gap, for example, via DRIE. The removal of the part of the first wafer at the end of the groove may be performed after the first wafer is bonded to the second wafer. Further grooves may be formed in the first wafer and part of the first wafer at an end of the further grooves may be removed to form further gaps. The further gaps may separate further pillars from the pillar. The method may further include filling the gap between the pillar and the cap structure with a mold compound. The mold compound may fill up any crevices between the pillars and the further pillars, as well as any crevices between the pillar and cap structure. The cavity between the cap structure and the second wafer may be free from the mold compound. The cavity may be configured to accommodate moving MEMS structures, also referred herein as MEMS devices. In other words, the cavity may provide room for holding the MEMS devices, as well as provide room for the MEMS devices to move or operate.

The step of filling the gap may be performed after the first wafer is bonded to the second wafer. A metal layer may optionally be deposited on the first wafer after forming the cavity and the groove in the first wafer. The metal layer may include at least one of titanium, copper, nickel or gold. A getter layer may be deposited in the cavity. The getter layer may include at least one of titanium or zirconium.

FIG. 1B shows a flow diagram 100B showing a method for fabricating a semiconductor package, according to various embodiments. The method may be similar to the method shown in the flow diagram 100A, in that it includes 102, 104 and 106. In addition, the method may include 108, in which at least one of a bonding pad or a sealing ring is formed on the first wafer; 110, in which part of the mold compound is ground away to expose the cap structure and the pillar; and 112, in which a redistribution layer (RDL) may be provided over a top surface of the mold compound, a top end of the pillar and a top surface of the cap structure, wherein each of the top surface of the mold compound, the top end of the pillar and the top surface of the cap structure face away from the second wafer. The top surface of the mold compound, the top end of the pillar and the top surface of the cap structure may form a flat surface. The at least one of the bonding pad or the sealing ring may include an alloy. The alloy may include at least one of aluminum, germanium, gold, indium, platinum, copper or tin. The RDL may be configured to provide an electricity conducting path between a metalized pad on an external surface of the RDL and the pillar. The external surface may oppose an internal surface, the internal surface being in contact with the pillar. The method may further include mounting solder balls or solder bumps on the RDL and may further include integrating an ASIC on the RDL. Integrating the ASIC on the RDL may include flip-chip bonding the ASIC to the metalized pad.

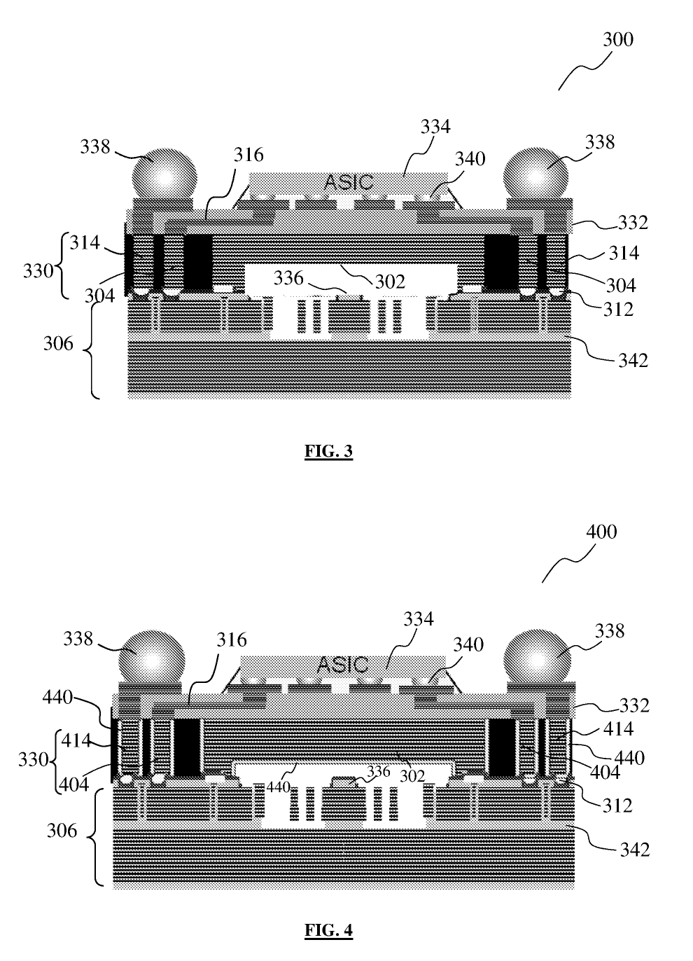

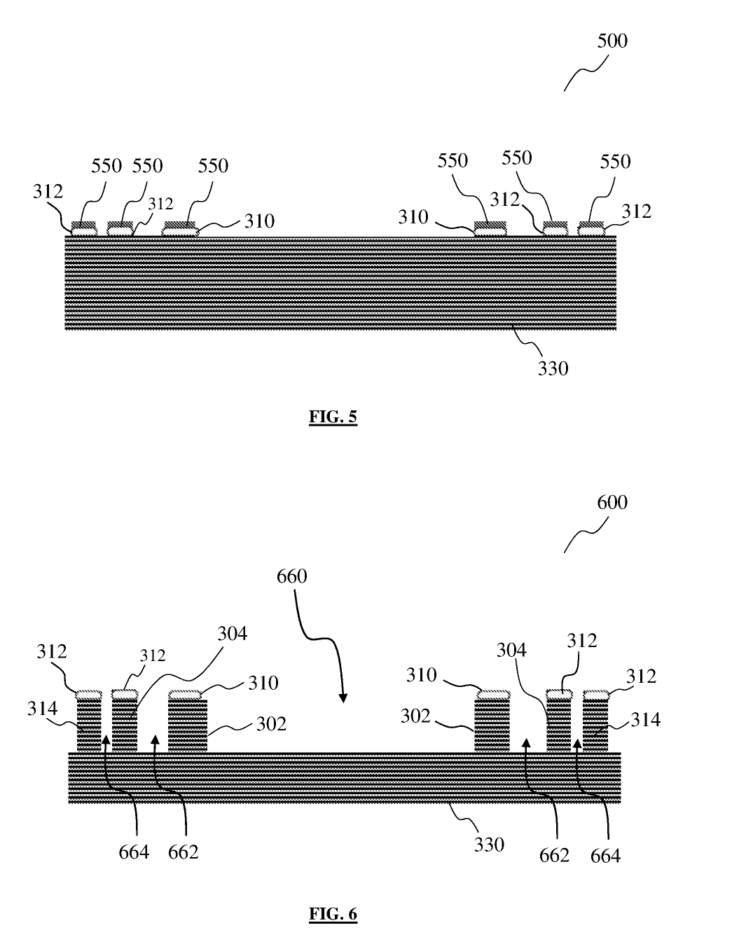

FIG. 2A shows a semiconductor package 200A according to various embodiments. The semiconductor package 200A may include a cap structure 202, a pillar 204, a second wafer 206 and a mold compound 208. The cap structure 202 and the pillar 204 may be formed from a first wafer. The pillar 204 may be separated from the cap structure 202 by a gap. The second wafer 206 may be bonded to the cap structure 202 and the pillar 204. The mold compound 208 may be between the pillar 204 and the cap structure 202. The first wafer may include conductive silicon. The conductive silicon may include doped silicon. Each of the pillar and the cap structure may optionally include a metal layer. The metal layer may include at least one of titanium, copper, nickel or gold. The second wafer 206 may include a MEMS device. The cap structure 202 may have a cavity formed therein, such that the cap structure 202 may be able to house a MEMS device therein. The cap structure 202 may form a sealed cavity with the second wafer 206. There may be a getter layer in the cavity. The getter layer may include at least one of titanium or zirconium.

FIG. 2B shows a semiconductor package 200B according to various embodiments. The semiconductor package 200B may be similar to the semiconductor package 200A, in that it may include a cap structure 202, a pillar 204, a second wafer 206 and a mold compound 208. The semiconductor package 200B may further include at least one of a sealing ring 210 on the cap structure 202 or a bonding pad 212 on the pillar 204; a further pillar 214; and a redistribution layer (RDL) 216. The at least one of a sealing ring 210 or a bonding pad 212 may include an alloy. The alloy may include at least one of aluminum, germanium, gold, indium, platinum, copper or tin. The further pillar 214 may be separated from the pillar 204 by a further gap. The RDL 216 may be arranged over a top surface of the mold compound 208, a top end of the pillar 204 and a top surface of the cap structure 202. Each of the top surface of the mold compound 208, the top end of the pillar 204 and the top surface of the cap structure 202 may face away from the second wafer 206. The top surface of the mold compound 208, the top end of the pillar 204 and the top surface of the cap structure 202 may form a flat surface. The RDL 216 may be configured to provide an electricity conducting path between a metalized pad on an external surface of the RDL 216 and the pillar 204, wherein the external surface opposes an internal surface. The internal surface may be in contact with the pillar 204. There may be solder balls mounted on the RDL 216. An ASIC may be integrated on the RDL 216. The ASIC may be flip-chip bonded onto the metalized pad.

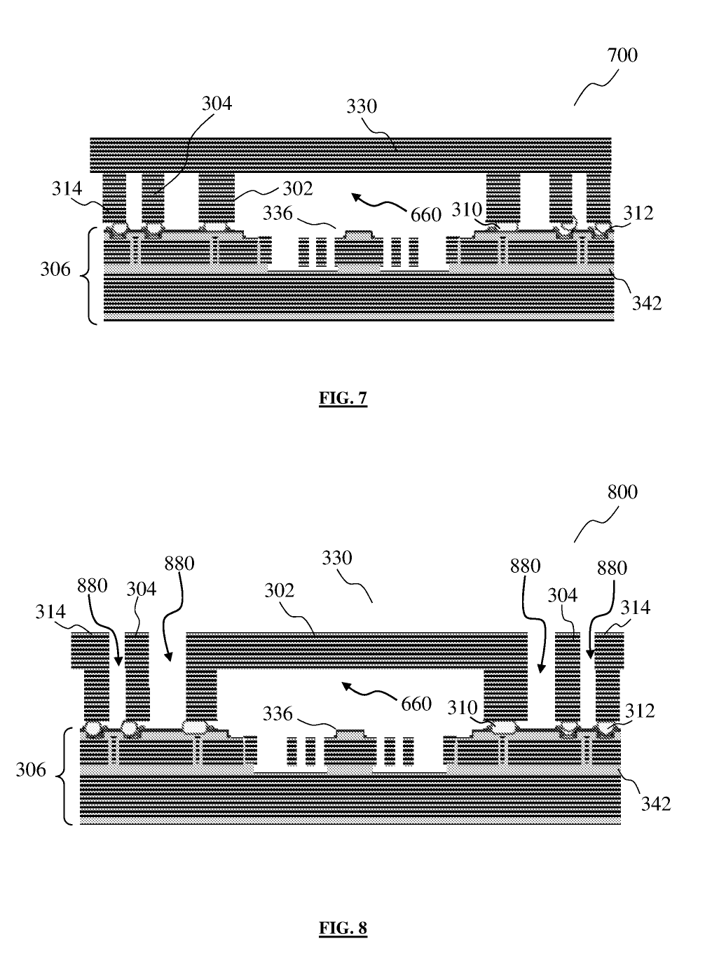

FIG. 3 shows a semiconductor package 300 according to various embodiments. The semiconductor package 300 may be at least substantially similar to the semiconductor package 200A of FIG. 2A or semiconductor package 200B of FIG. 2B. The semiconductor package 300 may include pillar structures; a cap structure 302; a device wafer 306; and mold compound 308. The pillar structures and the cap structure 302 may be formed from a cap wafer 330. The cap wafer 330 may be the first wafer referred to in the methods 100A and 100B. The cap wafer 330 may include a sealing ring. The sealing ring may be identical to the sealing ring 210 of the semiconductor package 200B. The pillar structures may include pillars 304 and further pillars 314. The pillars 304 may be identical to the pillars 204 of the semiconductor package 200A or 200B. The pillar structures may include high conductive silicon by virtue of the nature of the cap wafer 330. The further pillars 314 may be identical to the further pillars 214 of the semiconductor package 200B. The further pillars 314 may be identical to the pillars 304. The further pillars 314 may differ from the pillars 304 merely in that the further pillars 314 are not directly adjacent to the cap structure 302. The cap structure 302 may be identical to the cap structure 202 of the semiconductor package 200A or 200B.

The pillar structures may be electrically conductive, so as to conduct electricity between the MEMS device 336 and the electrical connection points of the semiconductor package 300. The electrical connection points may also be referred to as input/output (IO) pads. The mold compound 308 may be embedded within the cap wafer 330, separating the pillars 304 from the cap structure 302, and also separating the further pillars 314 from the pillars 304. Each pillar structure may be isolated from other pillar structures by the mold compound 308. For example, the mold compound 308 may be present between the pillar 304 and the further pillar 314. Each pillar structure and the cap structure 302 may be coupled to a bonding pad 312. The pillar structures may be bonded to the device wafer 306 by the bonding pads 312. The device wafer 306 may be identical to the second wafer 206 of the semiconductor package 200A or 200B. The device wafer 306 may include a MEMS device 336. The device wafer 306 may include electrical interconnects 342 within, for electrically coupling the MEMS device 336 to the pillars 304 and further pillars 314. The cap wafer 330 may be bonded to the device wafer 306, to encapsulate a MEMS device 336 on the device wafer 306. The cap structure 302 may hermetically seal the MEMS device 336 using the sealing ring. An insulation layer 332 may be provided above the cap wafer 330. The insulation layer may include a dielectric material. A redistribution layer (RDL) 316 may be provided above the cap wafer 330, such that the RDL 316 may be partially embedded within the insulation layer 332 and may be partially above the insulation layer 332. The RDL 316 may be identical to the RDL 216 of the semiconductor package 200B. The RDL 316 may include the electrical connection points or I/0 pads of the semiconductor package 300. The I/O pads may be provided above the insulation layer 332. Solder bumps or solder balls 338 may be provided on the electrical connection points. Microbumps 340 may also be provided on other parts of the RDL 316. An ASIC 334 may be bonded to the semiconductor package 300 via the microbumps 340 or the solder balls 338.

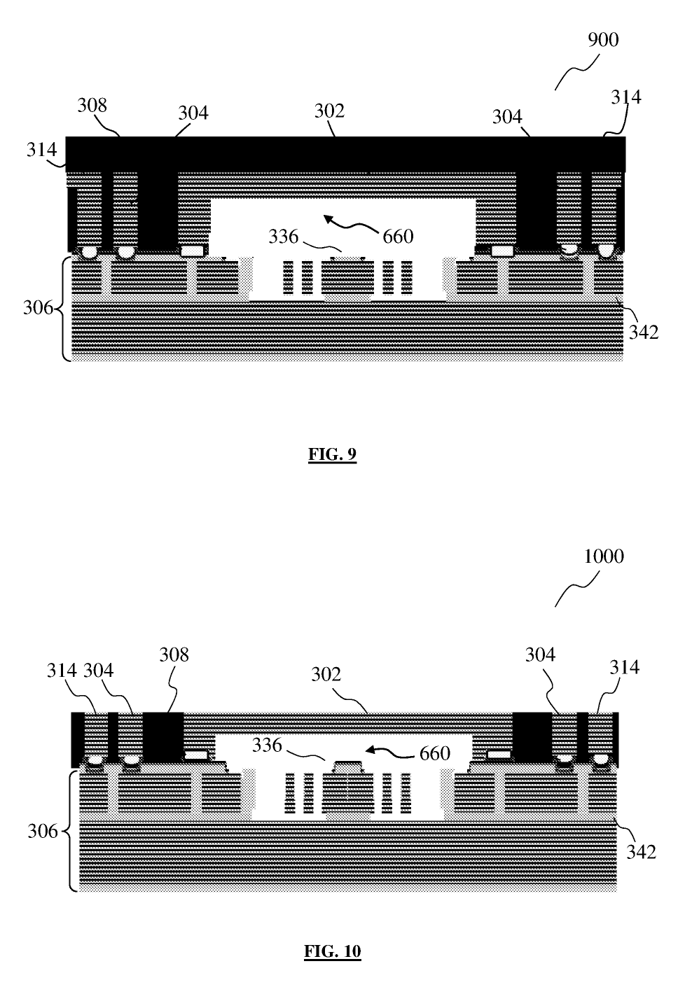

FIG. 4 shows a semiconductor package 400 according to various embodiments. The semiconductor package 400 may be similar to the semiconductor package 300 except that the pillar structures of the semiconductor package 400 may be metal-coated silicon instead of high conductive silicon. The pillar structures may include silicon pillar structures and a metal layer 440 over the silicon pillar structures. In other words, the pillar structures may be metal deposited silicon pillars. The pillar structures may include pillars 404 and further pillars 414. The pillar 404 may be the pillar 204 of the semiconductor package 200A or 200B. The further pillar 414 may be the further pillar 214 of the semiconductor package 200B. The pillar structures may be fabricated by applying a metallization process on the silicon. The metal layer 440 may include a conductive metal or a metal alloy. The metal layer 440 may include at least one of titanium, nickel, gold or copper. The metal deposited silicon pillars may serve as electrical interconnection structures in the semiconductor package 400. The metal deposited silicon pillars may extend through the mold compound 308 such that a first end of each pillar structure comes into contact with the device wafer 306 and a second end of the each pillar structure comes into contact with the electrical connection points.

Each of the semiconductor packages 300 and 400 may have its respective electrical interconnection array formed using the cap wafer 330 that is also used to form an encapsulation, instead of requiring TSV or TGV as in the state of the art wafer packages. The electrical interconnection array may be formed by etching the cap wafer 330 to form pillar structures. By doing so, each of the semiconductor packages 300 and 400 may overcome the technical limits of TSV and TGV wafers.

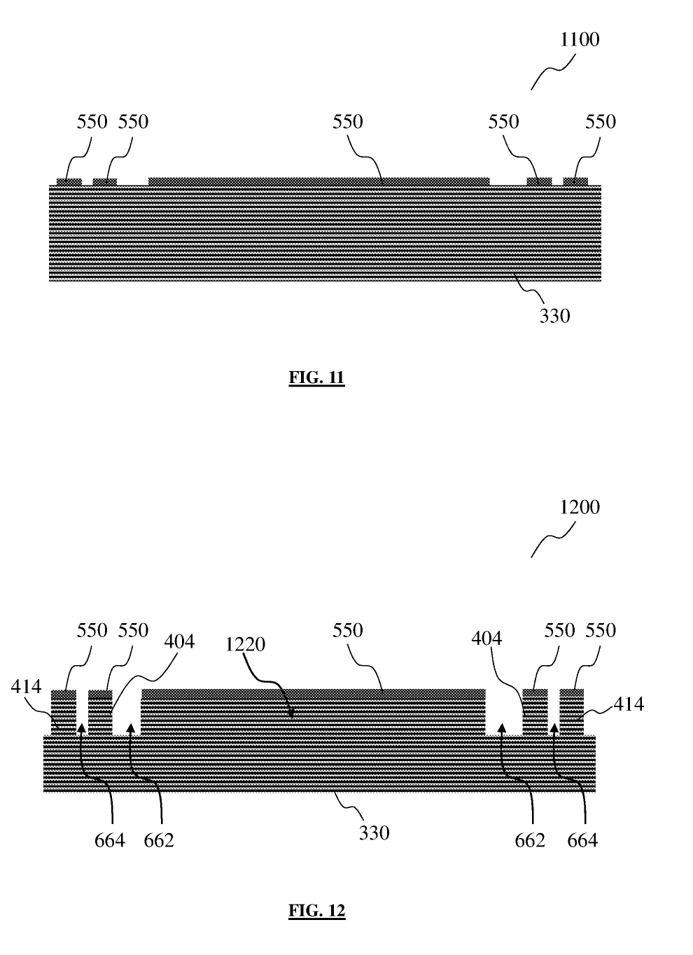

FIGS. 5-10 show various processes in a method for fabricating a semiconductor package according to various embodiments. The method may be referred herein as the first method. The semiconductor package may be at least substantially similar to the semiconductor package 200A, 200B, or 300. The semiconductor package may include at least one pillar structure that may be a high conductive pillar. In other words, the pillar structure may include high conductive silicon possessing electrical conductive characteristics.

FIG. 5 shows a process 500 in the first method. A cap wafer 330 may be provided. The cap wafer 330 may be the first wafer referred to in 102 of the method 100A or the method 100B. The cap wafer 330 may include high conductive silicon. Bonding pads 312 may be patterned onto the cap wafer 330. A sealing ring 310 may also be patterned onto the cap wafer 330. The bonding pads 312 may be the bonding pad 212 of the semiconductor package 200B and may also be the bonding pad referred to in 108 of the method 100B. The sealing ring 310 may be the sealing ring 210 of the semiconductor package 200B and may also be the sealing ring referred to in 108 of the method 100B. The sealing ring 310 may be at least substantially identical in composition as the bonding pad 312. Both the sealing ring 310 and the bonding pad 312 may be realized at the same time, during common deposition and patterning processes. The sealing ring 310 may be patterned on the cap wafer 330 where a cap structure is to be fabricated, so that the sealing ring 310 may serve to bond or seal the cap structure to a device wafer. The sealing as provided by the sealing ring 310 may be an air tight, i.e. hermetic seal. The bonding pads 312 may be provided on the cap wafer 330 where pillars are to be fabricated. The bonding pads 312 and the sealing ring 310 may include a metal or a metal alloy, such as one of aluminum-germanium, gold-indium, platinum-indium, copper-tin, or a combination thereof. An etching mask material 550 may be provided onto the bonding pads 312 and the sealing ring 310.

FIG. 6 shows a process 600 in the first method. The process 600 may be performed after the process 500. The process 600 may include an etching process. Deep reactive-ion etching (DRIE) may be performed to create a cavity 660 and at least one groove 662 and at least one further groove 664 in the cap wafer 330. The cavity area 660 may be a hollow space at least partially surrounded by a portion of the cap wafer 330. The portion of the cap wafer 330 that is surrounding the cavity area 660 may be referred herein as a cap structure 302. The cap structure 302 may be the cap structure 302 of the semiconductor package 300 or 400, or may be identical to the cap structure 202 of the semiconductor package 200A or 200B. The cap structure 302 may be the cap structure referred to in 102 of the method 100A or 100B. The groove 662 and the further groove 664 may define a pillar 304 in between. Another groove and the further groove 664 may define a further pillar 314 in between. By etching the grooves 662 and further grooves 664, at least one pillar structure may be formed in the cap wafer 330. The etching mask material 550 may be removed after the etching process is completed. A getter layer including getter materials such as titanium or zirconium may be deposited inside the cavity area 660 so that the cavity area 660 may be at least substantially free from gases after the cavity area 660 is sealed. The getter layer may absorb gases from the cavity area 660.

FIG. 7 shows a process 700 in the first method. The process 700 may be performed after the process 600. The process 600 may include a wafer bonding process. The cap wafer 330 obtained from performing the process 600 may be bonded to a device wafer 306. The device wafer 306 may be a wafer that includes a MEMS device 336. The device wafer 306 may further include interconnection 342 embedded within. The process 600 may bond an inner surface of the cap wafer 330 to the device wafer 306, the inner surface being a surface of the cap wafer 330 whereat the grooves 662, 664 and the cavity area 660 are formed. The wafer bonding process may hermetically seal the MEMS device 336 between the cap structure 302 and the device wafer 306, with the sealing ring 310. The wafer bonding process may also bond the pillar structures to the device wafer 306, with the bonding pads 312. The pillars 304 and the further pillars 314 may serve as an interconnection for signal delivery between the MEMS device 336 and a top surface of the semiconductor package. A first end of each of the pillar structures may be in contact with the bonding pad 312 and the bonding pad 312 may be in contact with the interconnection 342 of the device wafer 306. The interconnection 342 may be in contact with the MEMS device 336.

FIG. 8 shows a process 800 in the first method. The process 800 may be performed after the process 700. The cap wafer 330 may be etched to provide cavities for holding a mold compound. The process 800 may remove part of the cap wafer 330 that is at the end of the grooves 662 and further grooves 664, by etching. The removal of the end of the grooves 662 and the further grooves 664 may form gaps 880. The gaps 880 may be the cavities where the mold compound can be poured into. The etching may be performed using DRIE. In other words, the cap wafer 330 may be etched such that the cap structure 302 is no longer directly coupled to the pillars 304 and the further pillars 314 via the cap wafer 330. The cap wafer 330 may be etched such that the pillar 304 is no longer directly coupled to the further pillar 314 that is adjacent to the pillar 304. In other words, after the etching of the cap wafer 330, the cap wafer 330 becomes decoupled into a cap structure 302 and one or more standalone pillar structures, instead of being a contiguous piece of wafer.

FIG. 9 shows a process 900 in the first method. The process 900 may be performed after the process 800. The process 900 may include a molding process. A mold compound 308 may be poured into the cavities, i.e. gaps 880 in between the cap structure 302 and the pillars 304, as well as the gaps 880 between the pillars 304 and the further pillars 314. The mold compound 308 may fill the gaps between two bonded wafer pairs. The mold compound 308 may fill all crevices that may be reached. The mold compound 308 may not reach within the cavity area 660 which may be sealed by the cap structure 302 and the device wafer 306 using the sealing ring 310. The cavity area 660 may be vacuum sealed. The mold compound 308 may also be provided above the top surface of the cap structure 302 and the top ends of the pillar structures. The top surface may be the surface where etching was performed in the process 800. The top ends of the pillar structures may be level with the top surface. The top end of each pillar structure may oppose a bottom end, wherein the bottom end may be in contact with the bonding pads 312. The top end of each pillar structure may face away from the device wafer 306.

FIG. 10 shows a process 1000 in the first method. The process 1000 may be performed after the process 900. The process 1000 may include a grinding process. The mold compound 308 may be ground away until the top surface of the cap structure 302 and the top end of each of the pillars 304 and the further pillars 314 are exposed. After the grinding process, the top surface of the cap structure 302 may be level with a top surface of the mold compound 308. The top ends of the pillar structures may also be level with the top surface of the mold compound 308.

The first method may further include a RDL process. The RDL process may be performed after the process 1000. The semiconductor package after the completion of the RDL process may be the semiconductor package 300 of FIG. 3. The RDL process may generate a physical layout for integrating ASIC or other functional devices. The RDL process may provide a RDL 316, in other words, the physical layout for the interconnection between at least one of the exposed conductive silicon pillars 304 or the further pillars 314 and electrical connection points. The electrical connection points may be used for connecting the semiconductor package to an integrated circuit, such as an Application-specific integrated circuit (ASIC) 334. A flip-chip bonding process may be performed to integrate the ASIC device to the semiconductor package. A bumping process may be applied to generate bonding pads for ASIC device integration and bumps for board level interconnection. A first end of each of the pillars 304 and the further pillars 314 may be in contact with the bonding pad 312 which may be in contact with the device wafer 306. A second end of the each of the pillars 304 and the further pillars 314 may be in contact with the RDL 316. The electrical connection points may be metalized pads provided on top of the cap structure 302 and the pillars 304 or further pillars 314, but separated from the cap structure 302 and the pillars 304 and further pillars 314 by a dielectric layer 332. The dielectric layer 332 may serve as an insulation layer. The RDL 316 may provide signal paths between the silicon pillars and the metalized pads. The RDL 316 may include the metalized pads. After the RDL process is completed, solder balls 338 may be provided on the RDL 316 or the metalized pads, for bonding the semiconductor package to an external device such as a system board. The solder balls 338 may provide an electrical connection to the system board. Following the above described wafer level processing, the integrated devices may be separated into individual units, by a wafer sawing process.

The method as shown in FIGS. 5-10 may provide an interconnection between the MEMS device and the RDL, by creating pillars out of the cap wafer itself. In other words, the method may use the cap wafer for the via generation process. As such, the method may have the advantage that there is no need to form additional structures to provide the interconnection. The pillars may be formed simultaneously with the formation of the cavity area. As the vertically electrically conductive interconnects may be provided by the cap wafer itself, there may be no need to use conventionally used interconnection methods such as the through silicon via (TSV), through glass via (TGV) or through mold via (TMV). The vertically electrically conductive interconnects may be formed from silicon. The interconnection may be electrically conductive as the silicon is high conductive silicon. The high conductive silicon may be obtained by doping the silicon. The method may be used to manufacture wafer level packaging at low cost. The method may be applied to various MEMS device packaging and integration applications.

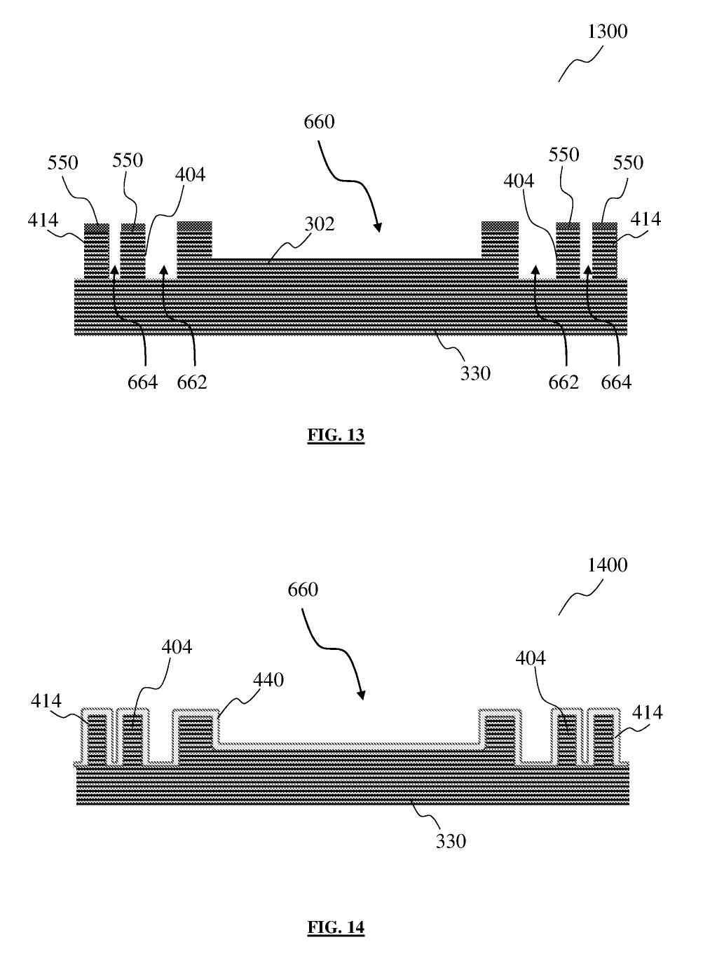

FIGS. 11-18 show a method for fabricating a semiconductor package according to various embodiments. The method may be referred herein as the second method. The method may be a wafer level MEMS packaging process that uses a normal silicon cap wafer instead of a high conductive silicon as in FIGS. 5-10. The method may provide an electrical path through the pillars, by having metal deposited onto the silicon pillar structures. In other words, the pillar structures may be metal deposited silicon pillars. The semiconductor package may be at least substantially similar to the semiconductor package 200A or the semiconductor package 200B.

FIG. 11 shows a process 1100 in the second method. A cap wafer 330 may be provided. The cap wafer 330 may be the first wafer referred to in 102 of FIG. 1A or 1B. The cap wafer 330 may include silicon. Etch mask material 550 may be deposited onto the cap wafer 330. The etch mask material 550 may be deposited on positions on the cap wafer 330, where pillar structures and a cap structure are to be fabricated. Optionally, a bonding metal layer may be patterned on the cap wafer 330, prior to the deposition of the etch mask material 550. The patterning of the bonding metal layer may include metalizing bonding pads onto the cap wafer 330 and may further include patterning a sealing ring on the cap wafer 330. The bonding metal layer may also be patterned to provide electrical RDL using the cap wafer surface.

FIG. 12 shows a process 1200 in the second method. The process 1200 may be performed after the completion of the process 1100. The process 1200 may include a first etching step. The first etching step may be a DRIE process. The process 1200 may etch the cap wafer 330 so as to create grooves 662 and further grooves 664. By creating the grooves 662 and further grooves 664, pillar structures may be generated. The pillar structures may include pillars 404 and further pillars 414. Unlike the process 600, the process 1200 may not include etching to form a cavity area. The process 1200 may carry on until a predetermined depth of the cap wafer 330 is etched, in other words, the pillar formed reaches the predetermined height. The pillar 404 may be identical to, or similar to, the pillar 204 of the semiconductor package 200A or 200B. The further pillars 414 may be identical to the pillars 404. The further pillars 414 may be identical to, or similar to, the further pillar 214 of the semiconductor package 200B. A pillar 404 may be separated from a further pillar by a groove 664 on one side of the pillar 404. A further groove 664 may be etched beside the pillar 404 on another side of the pillar 404, such that the pillar 404 is separated from a central portion 1220 of the cap wafer 330. The grooves 662 and the further grooves 664 may define the pillar structures. The silicon pillar structures, i.e. pillars 304 and further pillars 314 may become the interconnections in the semiconductor package subsequently after the following various processes.

FIG. 13 shows a process 1300 in the second method. The process 1300 may be performed after the completion of the process 1200. The process 1300 may include a second etching step. The second etching step may be a DRIE process to etch the cap wafer 330 so that a cavity area 660 may be formed. The cavity area 660 may be of a different depth as compared to the grooves 662 and further grooves 664. In other words, a lesser depth of silicon may be etched away to form the cavity area 660, as compared to the depth of silicon etched away to form the pillar structures. The silicon wafer material that is partially surrounding the cavity area 660 may be referred herein as the cap structure 302. The process 1300 may be performed separated from the process 1200 so that the cavity area may be etched to a different depth from the grooves 662 and further grooves 664, to provide proper individualization of the pillar structures which may serve as vertical interconnections of the semiconductor package. After the process 1300 is completed, the etch mask material 550 may be removed.

FIG. 14 shows a process 1400 in the second method. The process 1400 may be performed after the completion of the process 1300. The process 1400 may include a metal deposition process. A metal layer 440 may be deposited on both the cavity area 660 and the silicon pillar structures, in order to provide electrical conductive signal paths. The metal layer 440 may include bonding metal, i.e. a metal that is suitable for bonding two silicon wafers together. The metal layer 440 may include metals such as at least one of titanium, copper, nickel, gold or alloys thereof. A getter layer may also be deposited inside the cavity area to remove gases from the cavity area, thereby improving the quality of the vacuum in the cavity area 660 when the cavity area 660 is hermetically sealed. The getter layer may include getter materials such as titanium or zirconium. The getter layer may be arranged over the metal layer 440, inside the cavity area 660.

FIG. 15 shows a process 1500 in the second method. The process 1500 may be performed after the completion of the process 1400. The process 1500 may include a wafer bonding process. The cap wafer 330 may be bonded to a device wafer 306 so that a MEMS device 336 on the device wafer 306 may be hermetically sealed. The cap wafer 330 may be bonded to the device wafer 306 such that the bottom end of each pillar structure is facing the device wafer 306. During the bonding process, the metal layer 440 on the surfaces of the pillar structures and cap structure 402 that comes into contact with the device wafer 306 may melt. The melted metal layer 440 on the surfaces of the pillars 404 and further pillars 414 that come into contact with the device wafer 306 may be similar to the bonding pads 312 of FIGS. 3 and 4. The melted metal layer 440 on the surfaces of the cap structure that come into contact with the device wafer 306 may be similar to the sealing ring 210 of FIGS. 3 and 4. Alternatively, a sealing material, also referred herein as a bonding material, may be provided to bond the cap wafer 330 to the device wafer 306. The sealing material may be a metallic bonding material, for example an alloy including at least one of aluminum, germanium, gold, indium, platinum, copper and tin. The sealing material may be used to form the sealing ring 210 and the bonding pads 312. The sealing ring 210 may vacuum seal the cavity area 660. The bonding pads 312 may provide electrical coupling between the pillar structures and the device wafer 306. Through the bonding process, the pillar structures may be electrically coupled to the MEMS device such that the pillar structures may serve as interconnection for signal delivery.

FIG. 16 shows a process 1600 in the second method. The process 1600 may be performed after the completion of the process 1500. The process 1600 may include an etching process. The etching process may be performed by DRIE. A top surface, in other words, a top side of the cap wafer may be etched away by DRIE to provide the gap structures 1660 for mold compound to be poured in. The top surface of the cap wafer may face away from the device wafer. A portion of the cap wafer at a top end of the groove 662 may be etched away.

FIG. 17 shows a process 1700 in the second method. The process 1700 may be performed after the completion of the process 1600. The gaps between the cap structure and the pillars 404, i.e. the gaps 662 as shown in FIG. 16 may also be filled with the mold compound 308. The gaps between the pillar structures, i.e. the further gaps 664 as shown in FIG. 16 may also be filled with the mold compound 308. Crevices in the cap wafer may be filled with the mold compound 308 through at least one of wafer level compression or transfer molding process.

FIG. 18 shows a process 1800 in the second method. The process 1800 may be performed after the completion of the process 1700. The mold compound 308 may be ground off to expose the cap structure 402 and the pillar structures at a top surface of the mold compound. A top surface of each pillar structure may also be ground off so that the pillar structures that are still be connected as a contiguous wafer may be separated into individual pillar structures. In other words, the metal deposited pillars may now be individualized. A top surface of the cap structure 402 and a top surface of the mold compound 308 may also be further ground off so that the top surface of each of the pillar structures, the cap structure 402 and the mold compound 308 is at least substantially at a same height level.

The second method may further include a RDL process. The RDL process may be performed after the completion of the process 1800. After the completion of the RDL process, the semiconductor package may become the semiconductor package 400 of FIG. 4. In the RDL process, a signal layout and bonding pads may be generated using RDL while micro bumps and solder balls 338 may be deposited in the bumping process. The wafer level RDL process may be carried out to make the physical layout for interconnection between the exposed conductive silicon pillars and metalized pads on the semiconductor package. An insulator layer 332, for example, a dielectric layer, may be provided over the RDL 316. Metalized pads may be provided on the insulator layer 332 as part of the RDL 316. The pillar structures may be electrically coupled to the metalized pads through the RDL 316. The pillar structures may serve as signal paths, i.e. carry electrical signals from the MEMS device 336 to the metalized pads. The metalized pads may be the input/output pads of the semiconductor package. After the completion of the RDL process, a solder ball drop process may be carried out to provide solder compound on the semiconductor package. The metalized pads may be coupled to solder balls 338, for coupling with external devices, such as ASIC 314 or other functional devices. A flip-chip bonding process may be carried out to integrate the ASIC device 314 to the semiconductor package. The ASIC device 314 may be integrated on top of the cap structure 402. After the flip-chip bonding process, the individual integrated devices may be cut out from the wafer by a wafer sawing process.

The method as shown in FIGS. 11-18 may provide an interconnection between the MEMS device and the RDL, by creating pillars out of the cap wafer itself. In other words, the method may use the cap wafer for the via generation process. As such, the method may have the advantage that there is no need to form additional structures to provide the interconnection. As the vertically electrically conductive interconnects may be provided by the cap wafer itself, there may be no need to use conventionally used interconnection methods such as the through silicon via (TSV), through glass via (TGV) or through mold via (TMV). The vertically electrically conductive interconnects may be formed from silicon. The interconnects may be electrically conductive as the silicon pillars may be plated with an electrically conductive metal. The metal that may be deposited on the silicon pillar may serve to conduct electrical signals from the MEMS device to the ASIC that may be mounted on the semiconductor package. Unlike the method of FIGS. 5-10, the method of FIGS. 11-18 may form the cap structure and the pillar structures in two separate etching steps, instead of a single etching step. By having two separate etching steps, the cap structure may be fabricated to a different height from the pillar structures so that the cap structure may be retained even after the grinding process of process 1800.

According to various embodiments, a method for fabricating a semiconductor package may include forming a cap structure and a pillar from a first wafer. The process of forming the cap structure and the pillar from the first wafer may be shown in the processes 500 to 800 of the first method; and processes 1100 to 1600 of the second method. The pillar may be the high conductive silicon pillar of the first method and the semiconductor package 300; or the metal deposited silicon pillar of the second method and the semiconductor package 400. The first wafer may be referred herein as the cap wafer. In the first method, forming the pillar may include etching the first wafer, followed by bonding the first surface of the first wafer to a second wafer. The first surface of the first wafer may be the surface at which etching was performed on. Forming the pillar may further include etching the second surface of the first wafer after the first wafer is bonded to the second wafer. The second surface of the first wafer may oppose the first surface of the first wafer. The cap structure may be formed in the same steps as forming the pillar. In the second method, forming the pillar may include etching the first wafer on the first surface; depositing a metal layer on the pillar; bonding the first surface of the first wafer to the device wafer; then etching the second surface of the first wafer. The cap structure may be formed in a separate step in a second etching of the first surface. After the first surface of the first wafer has been bonded to the device wafer, the first wafer may be etched at the second surface to break away the cap structure from the pillar. The method may further include filling a gap between the pillar and the cap structure with a mold compound. The gap may be the space formed between the pillar and the cap structure, after process 800 of the first method or process 1600 of the second method. Forming the cap structure and the pillar from the first wafer may include forming a cavity and a groove in the first wafer, as shown in the process 600 of the first method or as shown in the processes 1200-1300 of the second method. The cavity may be a hollowed out space within the first wafer, for covering over a MEMS device on the device wafer, when the first wafer is flipped over, as shown in the process 700 of the first method. The groove may be a hollowed out space within the first wafer, for separating a small portion of the first wafer from another portion of the first wafer which surrounds the cavity. The small portion of the first wafer may become the pillar after a part of the first wafer at an end of the groove is etched away, as illustrated in the process 800 of the first method or the process 1600 of the second method. The cap wafer may include a further groove and part of the cap wafer at an end of the further groove may be removed to form a further gap. The further gap may separate a further pillar from the pillar. Each of the process 800 and the process 1600 may create openings for the mold compound to flow into the gap between the cap structure and the pillar, as well as the further gap between the pillar and the further pillar. The part of the cap wafer at an end of the further groove may be removed prior to filling the gap with the mold compound, if the pillar and the further pillar are strong enough to withstand the drag force of the flow of the mold compound. Alternatively, the part of the cap wafer at the end of the further groove may also be removed after the gap is filled with the mold compound, as in the process 1800. The pillar and the further pillar may be the high conductive silicon pillar or the metal deposited silicon pillar.

According to various embodiments, forming the cap structure and the pillar from the cap wafer may include one DRIE step to form a cavity and a groove in the cap wafer, wherein a depth of the cavity is at least substantially the same as a depth of the groove. The pillar may be the high conductive silicon pillar or the metal deposited silicon pillar.

According to various embodiments, forming the cap structure and the pillar from the cap wafer may also include two DRIE steps to form a cavity and a groove in the cap wafer, so that a depth of the cavity is shallower than a depth of the groove. The pillar may be the high conductive silicon pillar or the metal deposited silicon pillar.

According to various embodiments, the second method may also be utilized for providing via interconnection in conventional three-dimensional integrated circuit (3D IC) for package on package (POP) structure.

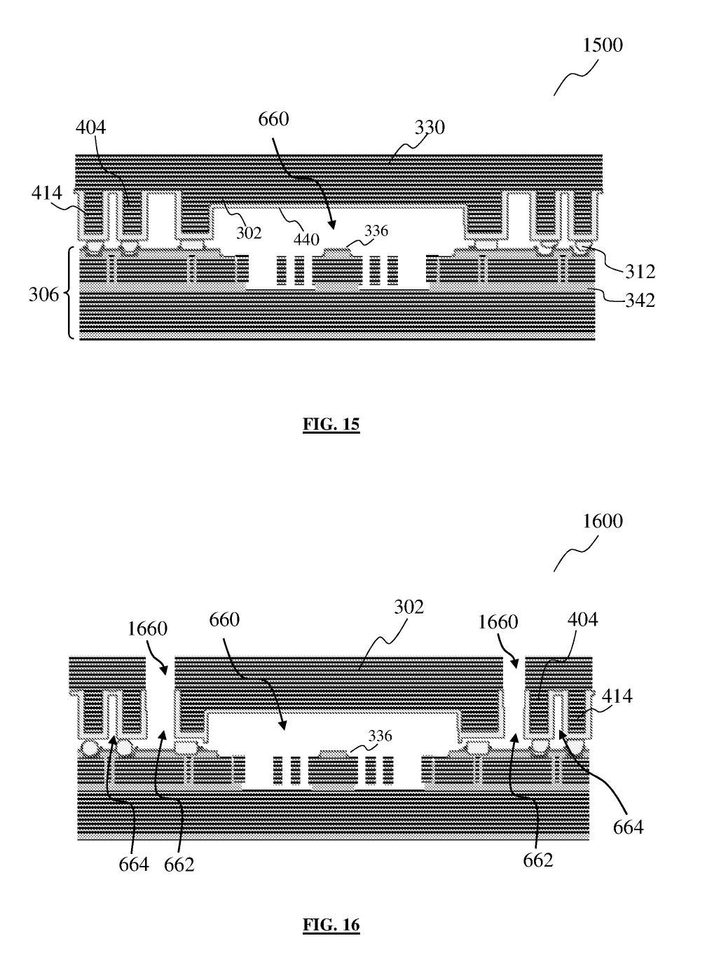

FIG. 19 shows a schematic diagram of a conventional POP structure 1900.

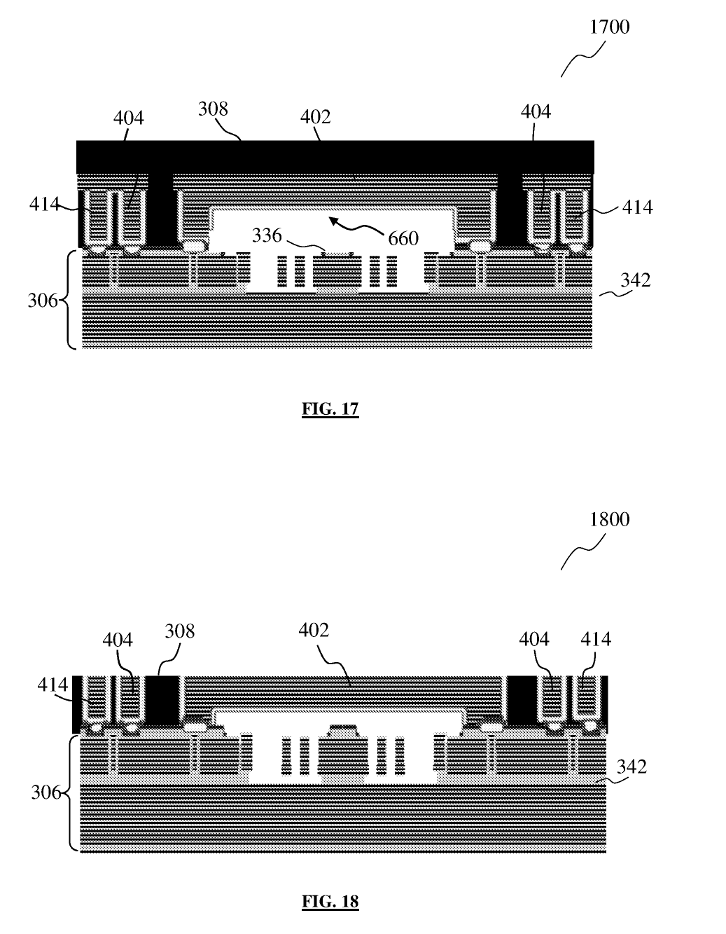

FIG. 20 shows semiconductor package 2000 according to various embodiments. The semiconductor package 2000 may be a POP structure including metal deposited silicon pillars 2020. The metal deposited silicon pillars 2020 may be at least substantially identical to, or similar to, the metal deposited silicon pillars 404 or further pillars 414. By using DRIE to etch the silicon wafer, very fine pitch interconnects may be achieved due to the anisotropic etching characteristics of silicon. The interconnects achieved maybe as small as submicron level. The interconnects may be silicon nanowires. With such small-sized interconnects, semiconductor packaging with high density vertical integrations may be manufactured.

According to various embodiments, the method may be further applied to fabricate high density interconnect for through mold via interconnect, for example, for high density fan out wafer level package and three-dimensional integrated circuit integration.

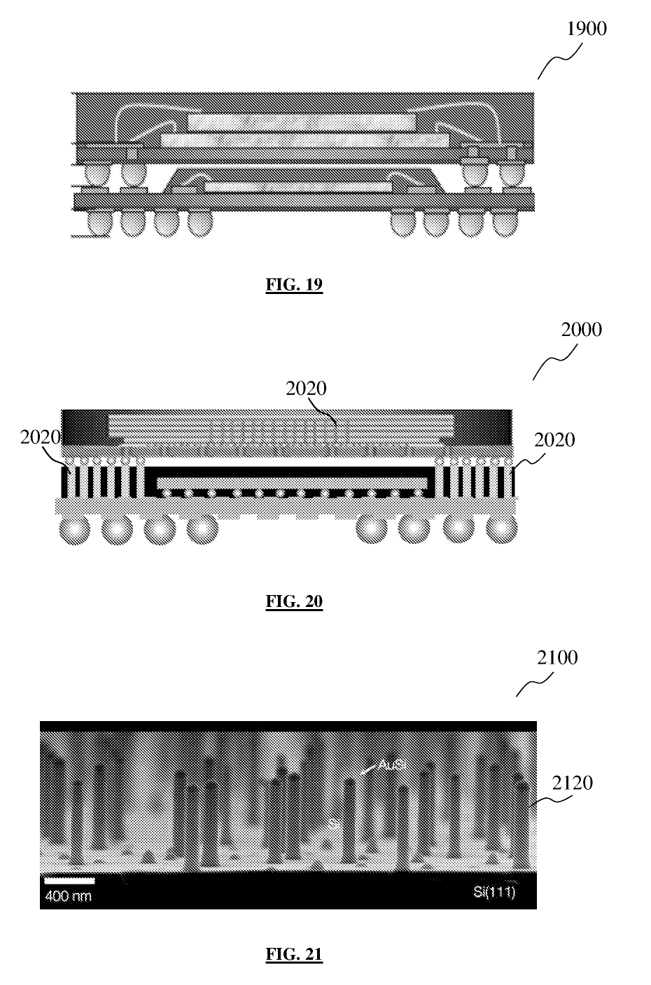

FIG. 21 shows a microscopic photograph 2100 of the metal deposited silicon pillars 2120. The pillars are coated with a metal layer. In this case, the metal layer includes gold.

According to various embodiments, the semiconductor package may have various advantages over state of the art methods, including using the silicon cap wafer as a conductive path; using mold compound to fill gaps in the semiconductor package and to provide redistribution of the signal paths; and may be integrated with a smaller-sized ASIC. Further, the ASIC chip may be integrated on the top of the cap wafer instead of being integrated on the device wafer. The interconnection may also provide interconnection on the surface of the semiconductor package, instead of having to be integrated chip-to-chip or face-to-face with an external device. State of the art semiconductor packages may have a step structure, but this problem is overcome in the semiconductor package according to various embodiments, by including a planarized mold surface. The resulting semiconductor package may be compact platform for read out integrated circuit integration. The semiconductor package may provide a more stable signal, as compared with the conventional wire bonding type packages. The semiconductor package may be used in various types of applications that require vacuum or hermetic sealing, such as MEMS sensor packaging.

While embodiments of the invention have been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced. It will be appreciated that common numerals, used in the relevant drawings, refer to components that serve a similar or the same purpose.

1. A method for fabricating a semiconductor package, the method comprising:
forming a cap structure and a pillar from a first wafer;
bonding the first wafer to a second wafer; and
filling a gap between the pillar and the cap structure with a mold compound.

2. The method of claim 1, wherein the gap between the pillar and the cap structure is filled with the mold compound after the first wafer is bonded to the second wafer.

3. The method of claim 1, further comprising:
forming at least one of a bonding pad or a sealing ring on the first wafer.

4. The method of claim 1, wherein forming the cap structure and the pillar from the first wafer comprises forming a cavity and a groove in the first wafer.

5. The method of claim 4, wherein forming the cavity and the groove in the first wafer comprises a first etching step and a second etching step.

6. The method of claim 5, wherein the first etching step comprises forming the groove and wherein the second etching step comprises forming the cavity, wherein the cavity has a different depth from the groove.

7. The method of claim 4, further comprising:
depositing a metal layer on the first wafer after forming the cavity and the groove in the first wafer.

8. The method of claim 4, wherein an inner surface of the first wafer is bonded to the second wafer after the cavity and the groove are formed, wherein the inner surface is a surface of the first wafer whereat the groove and the cavity are formed.

9. The method of claim 4, wherein forming the cap structure and the pillar from the first wafer further comprises removing part of the first wafer at an end of the groove to form the gap.

10. The method of claim 4, further comprising:
forming a further groove in the first wafer,
wherein part of the first wafer at an end of the further groove is removed to form a further gap,
wherein the further gap separates a further pillar from the pillar.

11. The method of claim 1, further comprising:
grounding away part of the mold compound to expose the cap structure and the pillar.

12. The method of claim 1, further comprising:
providing a redistribution layer over a top surface of the mold compound, a top end of the pillar and a top surface of the cap structure,
wherein each of the top surface of the mold compound, the top end of the pillar and the top surface of the cap structure face away from the second wafer.

13. The method of claim 12, wherein the top surface of the mold compound, the top end of the pillar and the top surface of the cap structure form a flat surface.

14. A semiconductor package comprising:
a cap structure and a pillar formed from a first wafer;
a second wafer bonded to the cap structure and the pillar; and
a mold compound between the pillar and the cap structure.

15. The semiconductor package of claim 14, wherein the second wafer comprises a MEMS device.

16. The semiconductor package of claim 14, wherein the first wafer comprises conductive silicon.

17. The semiconductor package of claim 14, further comprising:
at least one of a sealing ring on the cap structure or a bonding pad on the pillar.

18. The semiconductor package of claim 14, wherein each of the pillar and the cap structure comprises a metal layer.

19. The semiconductor package of claim 14, further comprising:
a further pillar,
wherein the further pillar is separated from the pillar by a further gap.

20. The semiconductor package of claim 14, further comprising:
a redistribution layer over a top surface of the mold compound, a top end of the pillar and a top surface of the cap structure,
wherein each of the top surface of the mold compound, the top end of the pillar and the top surface of the cap structure face away from the second wafer.
